(19) United States
(12) Patent Application Publication
(10) Pub. No.: US 2020/0404791 A1
(43) Pub. Date: Dec. 24, 2020

(54) ELECTRONIC ARRANGEMENT AND METHOD OF MANUFACTURING THE SAME

(71) Applicant: SIGNIFY HOLDING B.V., EINDHOVEN (NL)

(72) Inventors: LIHUA LIN, EINDHOVEN (NL); WOUTER OEPTS, EINDHOVEN (NL)

(21) Appl. No.: 16/978,665

(22) PCT Filed: Mar. 11, 2019
(86) PCT No.: PCT/EP2019/055961

§ 371 Date: Sep. 4, 2020

(30) Foreign Application Priority Data
Mar. 16, 2018 (CN) PCT/CN2018/079347
May 9, 2018 (EP) 18171407.2

(51) Int. Cl. H05K 1/18; H01L 25/075; H01L 33/62; H05K 3/34

(52) U.S. Cl. CPC H05K 1/189; H01L 25/0753; H01L 33/647; H05K 3/34; H01L 33/62

(57) ABSTRACT

An electronic arrangement (100) and a method of manufacturing an electronic arrangement are provided. The electronic arrangement comprises an array of electronic components (110) arranged along a first axis, A, and a carrier (120) arranged to support the array of electronic components, wherein the carrier comprises, a first metal layer (130), a second metal layer (140), and an at least partially insulating layer (150) arranged between the first and second metal layers. The electronic arrangement further comprises a partition portion (160) arranged between two adjacently arranged electronic components for partitioning the electronic arrangement, wherein the second metal layer comprises a void (180) intersected by the second axis, wherein the void has a width (190) which extends parallel to the first axis, such that, at the second axis, the second metal layer is undercut with respect to the first metal layer, in a direction parallel to the first axis.

### FIELD OF THE INVENTION

The present invention generally relates to the field of electronic arrangements, such as printed circuit boards, and methods of manufacturing such electronic arrangements.

### BACKGROUND OF THE INVENTION

The use of light-emitting diodes (LED) for illumination purposes continues to attract attention. Compared to incandescent bulbs, LEDs provide numerous advantages such as a longer operational life and an increased efficiency related to the ratio between light energy and heat energy. LED lamps may be used for a general lighting or even for a more specific lighting, as the color and the output power of the LEDs may be tuned.

Many light-emitting arrangements in the prior art, which comprise LEDs, further comprise a printed circuit board (PCB) upon which the LEDs are arranged. The PCB may comprise an electrical insulating layer (e.g. a dielectric layer or a glass fibre-filled epoxy layer) and a metal layer provided below the insulating layer, arranged for heat conduction. It should be noted that light-emitting arrangements comprising a plurality of electronic components (e.g. LEDs) may generate a quick rise of the temperature of the light-emitting arrangement, and the effect of heat may be detrimental to the electronic components.

Flexible PCBs (also denoted FPC), and in particular metal-layer FPCs, have recently become popular in the lighting industry. The benefits of metal-layer FPCs are numerous. First, it will be appreciated that metal-layer FPCs are able to provide a relatively high thermal performance, which may be more efficient that standard FPCs and comparable to that of metal-core PCBs (MCPCBs). Hence, the metal-layer PFCs may thereby contribute to the heat management of the lighting arrangement. Second, the metal-layer FPCs are associated with a relatively low material cost, e.g. compared to MCPCBs. Third, due to their flexibility, the metal-layer FPCs may be deformed such that they may be shaped in three dimensions (3D).

Due to the increasing demands on size differentiation of arrangements comprising electronic components and PCBs from the lighting industry, there is a need to further explore the configuration of such arrangements. This may be of particular interest in the case of providing and/or adapting arrays of such arrangements.

However, MCPCBs arranged in an array according to the prior art are usually not easily separable. Furthermore, separated MCPCBs may suffer from problems related to creepage, i.e. current leakage between conductive layers in the PCBs. In other words, after separation or cutting of MCPCBs, there may be a (too) small creepage distance between the conductive layers in the PCBs.

Hence, alternative solutions are of interest which are able to provide a PCB structure which is conveniently separable and which furthermore may overcome, or at least alleviate, the problem of a too small creepage distance.

### SUMMARY OF THE INVENTION

It is an object of the present invention to mitigate the above problems and to provide a lighting device, as well as a method of manufacturing the lighting device, which is convenient, efficient and/or cost-effective.

This and other objects are achieved by providing a lighting device and a method of manufacturing a lighting device having the features in the independent claims. Preferred embodiments are defined in the dependent claims.

Hence, according to a first aspect of the present invention, there is provided an electronic arrangement. The electronic arrangement comprises an array of electronic components arranged on a layer of a layer stack and along a first axis and the layer stack being formed as a carrier arranged to support the array of electronic components. The carrier comprises, in a direction perpendicular to the first axis and perpendicular to the layer stack, a first metal layer and a second metal layer, wherein an at least partially insulating layer is arranged between the first and second metal layers. The electronic arrangement further comprises at least one partition portion arranged between two adjacently arranged electronic components for partitioning the electronic arrangement along a second axis of the at least one partition portion, wherein the second axis extends perpendicular to the first axis. The second metal layer, at the at least one partition portion, comprises a void which is intersected by the second axis. wherein the at least one void has a width which extends parallel to the first axis, such that, at the second axis, the second metal layer is undercut with respect to the first metal layer, in a direction parallel to the first axis.

According to a second aspect of the present invention, there is provided a method of manufacturing an electronic arrangement. The method comprises the step of providing a layer stack as a carrier, including arranging a first metal layer on an at least partially insulating layer, wherein the first metal layer and the at least partially insulating layer extend along a first axis. The method comprises the step of providing a second metal layer extending along the first axis and forming at least one void in the second metal layer having a width which extends parallel to the first axis. The method further comprises the step of arranging a plurality of electronic components in an array on the carrier along the first axis. The method comprises the step of forming at least one partition portion between two adjacently arranged electronic components for partitioning the electronic arrangement along a second axis, B, of the at least one partition portion perpendicular to the first axis by arranging the second metal layer under the at least partially insulating layer such that the at least one void is intersected by the second axis and such that, at the second axis, the second metal layer is undercut with respect to the first metal layer, in a direction parallel to the first axis.

Thus, the present invention is based on the idea of providing an electronic arrangement having one or more partition portions arranged between two adjacently arranged electronic components of the electronic arrangement, wherein the second metal layer, at the partition portion(s), comprises at least one void. Due to the void(s) of the second metal layer, the second metal layer is undercut with respect to the first metal layer. Consequently, a partitioning or cutting of the electronic arrangement at the void(s) between two adjacently arranged electronic components lead to a sufficiently large creepage distance between the first and second metal layers for the purpose of minimizing leakage currents between the first and second metal layers.

The present invention is advantageous in that a partitioning (cutting, separation) of the electronic arrangement at the void(s) of the partition portion(s) conveniently provides a sufficiently large creepage distance between the first and second metal layers. Hence, the electronic arrangement may overcome the problem of a too small creepage distance between the conductive first and second metal layers after a partitioning of the electronic arrangement.

The present invention is further advantageous in that the provision of void(s) of the second metal layer of the electronic arrangement may lead to a facilitated partitioning (cutting) operation of the second metal layer. In other words, the void(s) of the second metal layer, i.e. the absence of material, ensures a more convenient and/or faster partitioning or separation of the electronic arrangement at its partition portion(s).

The present invention is further advantageous in that the inventive configuration of the electronic arrangement leads to an increased cost- and/or time efficiency upon manufacturing and/or partitioning (cutting) of the electronic arrangement. More specifically, due to the provision of void(s) in the second material layer of the electronic arrangement, less material is used in the electronic arrangement compared to arrangements in the prior art. Consequently, the electronic arrangement becomes relatively cost-efficient. Furthermore, as the provision of void(s) leads to a more easily and conveniently partitioned electronic arrangement, the wear of the tool(s) for partitioning (cutting) the electronic arrangement may be minimized.

The electronic arrangement comprises an array of electronic components arranged along a first axis, and a carrier arranged to support the array of electronic components. By the term “carrier”, it is hereby meant a substrate, a printed circuit board, or the like. The carrier comprises, in a direction perpendicular to the first axis, a first metal layer and a second metal layer, wherein an at least partially insulating layer is arranged between the first and second metal layers. Hence, the first metal layer, the at least partially insulating layer, and the second metal layer are arranged on top of each other in a sandwich construction of the electronic arrangement.

The electronic arrangement further comprises one or more partition portions arranged between two adjacently arranged electronic components. By the term “partition portion”, it is hereby meant a portion of the electronic arrangement at which the electronic arrangement is configured to be partitioned or cut.

The second metal layer, at the at least one partition portion, comprises at least one void intersected by the second axis. By the term “void”, it is hereby meant a cut, a hole, an opening, or the like, of the second metal layer. The at least one void has a width which extends parallel to the first axis, such that, at the second axis, the second metal layer is undercut with respect to the first metal layer, in a direction parallel to the first axis. Hence, the first metal layer projects over the second metal layer relative the second axis.

It will be appreciated that the electronic arrangement of the present invention may comprise or constitute a flexible PCB (also denoted FPC), and in particular a metal-layer FPC.

According to an embodiment of the present invention, the width of the at least one void may be dependent on the distance between adjacently arranged electronic components, in particular the width of the at least one void is in the range of 0.5-1.1 times the distance (L) between adjacently arranged electronic components, for example in the range of 0.7-1.1 or in the range of 0.9-1.1 times said distance (L). In other words, the width of the void(s) at the partition portion(s) may be dependent on the distance between (two) adjacently arranged electronic components on either side of the partition portion(s). The embodiment is advantageous in that a location of the cut can be relatively accurately indicated by the void and that unintentionally cutting into an electronic component on either side of the void is counteracted.

According to an embodiment of the present invention, the width of the at least one void may be dependent on the thickness of the at least partially insulating layer. Hence, the width of the one or more voids parallel to the first axis may be provided as a function of the thickness of the at least partially insulating layer. In particular the width of the at least one void is negatively correlated to the thickness of the at least partially insulating layer, i.e. higher values of said width are associated with lower values of said thickness. The embodiment is advantageous in that the electronic arrangement may be conveniently adapted to provide a desired creepage distance after partitioning of the electronic arrangement. For example, in case the at least partially insulating layer is relatively thin, the width of the one or more voids may be relatively large in order to create a sufficiently large creepage distance. Conversely, in case the at least partially insulating layer is relatively thick, and thereby significantly contributes to the creepage distance of the electronic arrangement, the width of the one or more voids may be relatively small.

According to an embodiment of the present invention, the sum of the thickness of the at least partially insulating layer and half the width of the void is 0.1-3 mm, preferably 0.5-1.2 mm, and most preferred 0.5-0.7 mm. It will be appreciated that in case the electronic arrangement is partitioned (cut) at its partition portion(s), the creepage distance D of the electronic arrangement between the first and second metal layers may be defined as the sum of the thickness T of the at least partially insulating layer and half the width W of the void, i.e. D=T+W/2. The embodiment is advantageous in that in case the sum of the thickness of the at least partially insulating layer and half the width of the void constitutes 0.1-3 mm, the creepage distance may be sufficient to comply to at least the majority of isolated and non-isolated driver systems of the electronic arrangement in LED systems. Furthermore, in case the sum of the thickness of the at least partially insulating layer and half the width of the void constitutes 0.5-1.2 mm, such as 0.5-0.7 mm, the creepage distance may comply with specific requirements of isolated driver systems.

According to an embodiment of the present invention, the at least one void may have a rectangular shape. The embodiment is advantageous in that the creepage distance of the electronic arrangement after its partitioning (cutting) hereby may be conveniently defined.

According to an embodiment of the present invention, the second metal layer may comprise aluminum, Al. The embodiment is advantageous in that the electronic arrangement comprising aluminum is associated with a relatively low cost, has a relatively high thermal performance and enables 3D-shapes of the electronic arrangement. Furthermore, the electronic arrangement comprising aluminum is relatively easy to cut. In contrast, it should be noted that MCPCBs of the prior art often are difficult to cut, as the metals used are often relatively thick.

According to an embodiment of the present invention, the thickness of the second metal layer is 0.1-1.6 mm, preferably 0.2-0.5 mm, and most preferred 0.24-0.36 mm. It will be appreciated that a second metal layer of the electronic arrangement having a thickness in the range of 0.2-0.5 mm (e.g. of Al) may be conveniently cuttable, whereas thicker dimensions of the second metal layer may need auxiliary cutting processes and/or tools. Furthermore, and in particular if providing Al as the second metal layer, the thickness of the second metal layer may conveniently be approximately 0.3 mm.

According to an embodiment of the present invention, at least one of the at least partially insulating layer and the first metal layer may comprise an indentation at the at least one partition portion. Hence, an indentation may be provided in one or more of the at least partially insulating layer and the first metal layer at the partition portion(s) of the electronic arrangement. The embodiment is advantageous in that the indentation(s) of the at least partially insulating layer and/or the first metal layer may facilitate a partitioning (cutting) at the partition portion(s).

According to an embodiment of the present invention, at least one of the electronic components may comprise at least one light-emitting diode, LED.

According to an embodiment of the present invention, there may be provided an electronic board comprising a plurality of electronic arrangements according to any one of the preceding embodiments. The electronic arrangements may be arranged side-by-side in a first plane such that partition portions of adjacently arranged electronic arrangements are arranged along the second axis in the first plane for partitioning the electronic board along the second axis. In other words, the electronic board may extend in 2D in a first plane and be partitioned (cut) into smaller portions or segments along the second axis. The embodiment is advantageous in that the manufacturing of an electronic board intended for subsequent partitioning may be even more cost- and/or time efficient compared to a manufacturing and/or partitioning of electronic arrangements as previously described.

According to an embodiment of the method of the present invention, the at least one void may have a rectangular shape. The embodiment is advantageous that a rectangular void (hole) may be conveniently cut in the second metal layer of the electronic arrangement.

According to an embodiment of the method of the present invention, the second metal layer may comprise aluminum, Al.

According to an embodiment of the method of the present invention, the thickness of the second metal layer may be 0.1-1.6 mm, preferably 0.2-0.5 mm, and most preferred 0.24-0.36 mm. It will be appreciated that the method of the present invention may conveniently cut through the second metal layer of the presented thicknesses, often without requiring auxiliary tools and/or specific cutting methods.

According to an embodiment of the method of the present invention, the method may further comprise forming at least one indentation in the at least partially insulating layer and the first metal layer at the at least one partition portion. By forming the mentioned indentation(s) in the at least partially insulating layer and/or the first metal layer at the partition portion(s) of the electronic arrangement, a partitioning (cutting) at the partition portion(s) may be facilitated.

Further objectives of, features of, and advantages with, the present invention will become apparent when studying the following detailed disclosure, the drawings and the appended claims. Those skilled in the art will realize that different features of the present invention can be combined to create embodiments other than those described in the following.

### BRIEF DESCRIPTION OF THE DRAWINGS

This and other aspects of the present invention will now be described in more detail, with reference to the appended drawings showing embodiment(s) of the invention.

FIGS. 1a-b are schematic, cross-sectional views of a metal-core PCB (MCPCB) according to the prior art;

FIGS. 2a-b are schematic, cross-sectional views of an electronic arrangement according to an exemplifying embodiment of the present invention;

FIG. 3 is a schematic, cross-sectional view of an electronic arrangement according to an exemplifying embodiment of the present invention;

FIGS. 4a-b are schematic top and bottom views, respectively, of an electronic arrangement according to an exemplifying embodiment of the present invention;

FIGS. 5a-b are schematic top and bottom views, respectively, of an electronic board according to an exemplifying embodiment of the present invention; and

FIG. 6 is a schematic illustration of a method of manufacturing an electronic arrangement according to an exemplifying embodiment of the present invention.

### DETAILED DESCRIPTION

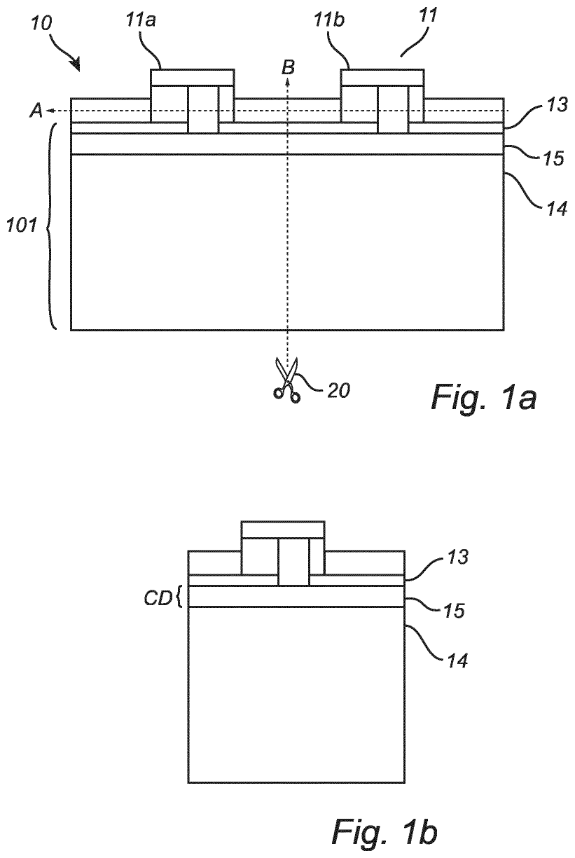

FIG. 1a is a schematic, cross-sectional view of a metal-core PCB (MCPCB) 10 according to the prior art. The MCPCB 10 comprises a plurality of electronic components 11, which are exemplified as a first LED element 11a and a second LED element 11b. The electronic elements 11 are arranged along a horizontally extending first axis A. The MCPCB 10 further comprises a first metal layer 13 and a second metal layer 14, and a layer 15 which is arranged between the first metal layer 13 and the second metal layer 14.

The MCPCB 10 may be cut along a second axis B extending perpendicular to the first axis A. The partitioning or cutting of the MCPCB 10 is schematically indicated by the pair of scissors 20, which eventually separates the first LED element 11a and the second LED element 11b of the MCPCB 10. After cutting, the resulting right (or left) hand portion of the MCPCB 10 in FIG. 1a is schematically shown in FIG. 1b. However, the distance CD (which furthermore may be denoted as the creepage distance CD) between the first metal layer 13 and the second metal layer 14 along the layer 15 may hereby be relatively small. More specifically, this creepage distance CD between the conductive first and second metal layers 13, 14 may be in the order of the thickness of the layer 15, such as e.g. 0.1 mm. This is generally a too small creepage distance, and may lead to leakage currents between the conductive first and second metal layers 13, 14.

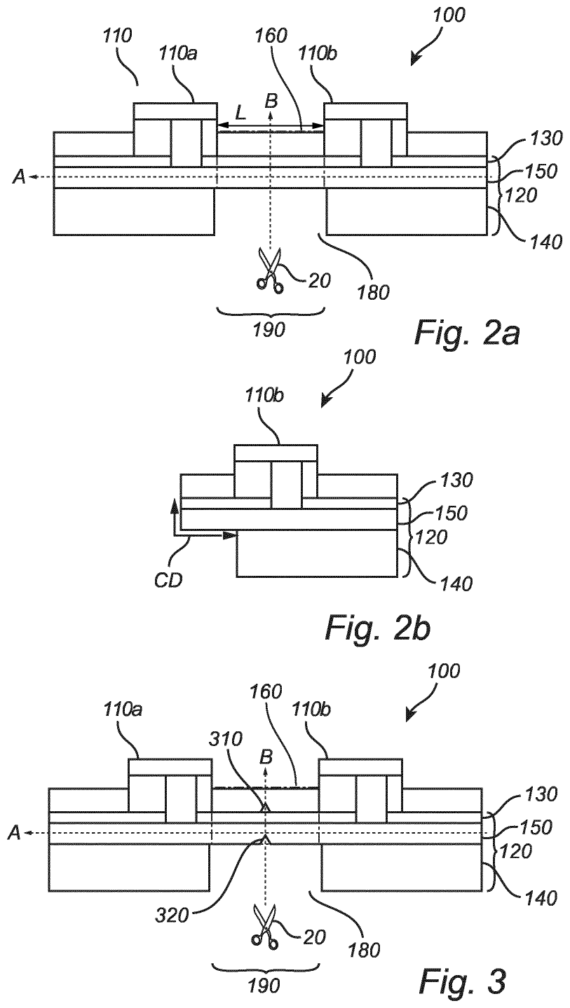

FIG. 2a is a schematic, cross-sectional view of an electronic arrangement 100 according to an exemplifying embodiment of the present invention. The electronic arrangement 100 comprises an array of electronic components 110 arranged along a first axis, A, which extends horizontally. The electronic components 110, which are exemplified as two electronic components 110a, 110b which are spaced apart along the first axis A, may for example comprise one or more LEDs.

The electronic arrangement 100 comprises a carrier 120 which is arranged to support the array of electronic components 110. The carrier 120 comprises, in a direction perpendicular to the first axis A, a first metal layer 130 and a second metal layer 140. The first metal layer 130 may, for example, comprise or be made of copper (Cu). The thickness of the first metal layer 130 may, for example, be 35-70 μm. The second metal layer 140 may, for example, comprise or be made of aluminum (Al). The thickness of the second metal layer 140 may, for example, be 0.1-1.6 mm, such as 0.2-0.5 mm, such as 0.24-0.36 mm, or approximately 0.3 mm. The carrier 120 further comprises an at least partially insulating layer 150 which is arranged between the first metal layer 130 and the second metal layer 140. The thickness of the at least partially insulating layer 150 may, for example, be 75-150 μm.

The electronic arrangement 100 further comprises at least one partition portion 160. The partition portion 160 is arranged between the two adjacently arranged electronic components 110a, 110b for partitioning (cutting) the electronic arrangement 100 along a second axis B of the at least one partition portion 160, wherein the second axis B extends perpendicular to the first axis A. The intended partitioning (cutting) along the second axis B is schematically indicated by a pair of scissors 20.

At the partition portion 160 of the electronic arrangement 100, the second metal layer 140 comprises at least one void 180 which is intersected by the second axis B. The at least one void 180 has a width 190 which extends parallel to the first axis A, such that, at the second axis B, the second metal layer 140 is undercut with respect to the first metal layer 130, in a direction parallel to the first axis A. This configuration of the electronic arrangement 100 leads to a relatively large creeping distance between the first metal layer 130 and the second metal layer 140 after cutting the electronic arrangement 100 at the partition portion 160 and along the second axis B as indicated in FIG. 2. The width 190 of the at least one void 180 may be dependent on the distance L between adjacently arranged electronic components 110a, 110b. For example, the width 190 of the at least one void 180 may be not less than L, or be in the range of 0.9-1.1 times the distance L between (two) adjacently arranged electronic components 110a, 110b on either side of the partition portion 160.

After partitioning or cutting the electronic arrangement 100 at the partition portion 160 and along the second axis B, the resulting right (or left) hand portion of FIG. 2a is schematically shown in FIG. 2b. The L-shaped distance CD (which furthermore may be denoted as the creepage distance CD) between the first metal layer 130 and the second metal layer 140 along the at least layer 15 may hereby be sufficiently large for minimizing or completely avoiding leakage currents between the conductive first metal layer 130 and the second metal layer 140. More specifically, as the second metal layer 140 is undercut with respect to the first metal layer 130, in a direction parallel to the first axis A and at the second axis B, the L-shaped creepage distance CD between the conductive first and second metal layers 130, 140 may be in the order of the sum of the thickness of the at least partially insulating layer 150 and half the width of the at least one void 180. In combination herewith, the width of the at least one void 180 may be dependent on the thickness of the at least partially insulating layer 150. For example, in case the at least partially insulating layer 150 is relatively thin, the width of the one or more voids 180 may be relatively large. Hence, as a consequence, the second metal layer 140 may be undercut to a relatively large degree with respect to the first metal layer 130 in order to create a sufficiently large creepage distance CD. In contrast, in case the at least partially insulating layer 150 is relatively thick, the width of the one or more voids 180 may be relatively small. In other words, the second metal layer 140 may be undercut to a relatively small degree with respect to the first metal layer 130, as the at least partially insulating layer 150 by virtue of its thickness may contribute to a large extent to the creepage distance CD of the electronic arrangement 100. The creepage distance CD may be 0.1-3 mm, such as 0.5-1.2 mm, such as 0.5-0.7 mm. The thickness of the second metal layer may be 0.1-1.6 mm, such as 0.2-0.5 mm, such as 0.24-0.36 mm. In particular, if Al is provided as the second metal layer, the thickness of the second metal layer of Al may be approximately 0.3 mm.

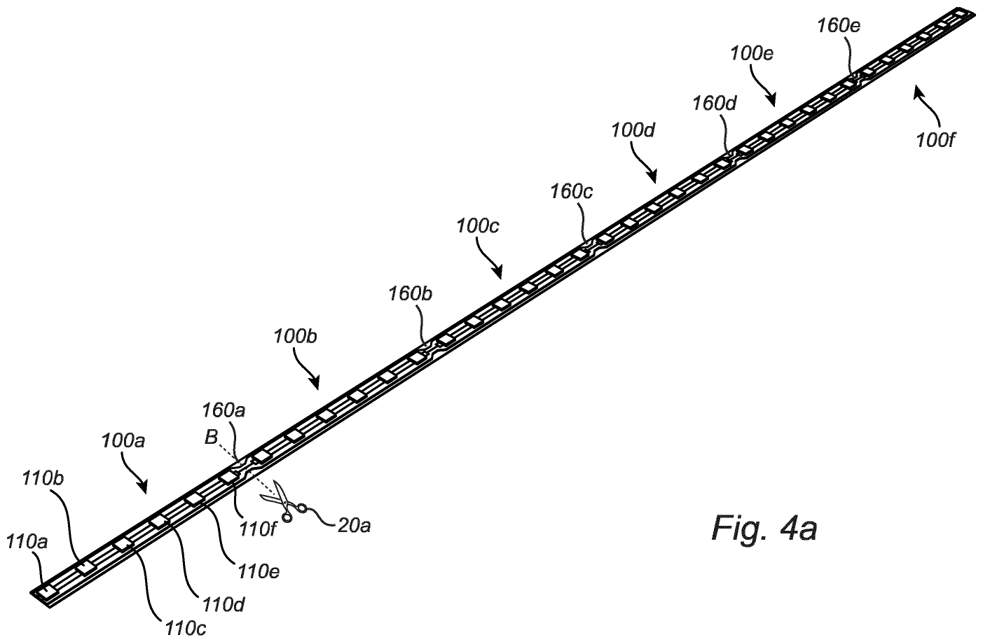

FIG. 3 is a schematic, cross-sectional view of an electronic arrangement 100 according to an exemplifying embodiment of the present invention. The electronic arrangement 100 as shown has many features in common with the electronic arrangement 100 of FIG. 2a, and it is hereby referred to the caption of FIG. 2a for an increased understanding of the partitioning operation of the electronic arrangement 100. In FIG. 3, the at least partially insulating layer 150 and the first metal layer 130 comprise a respective indentation 310, 320 at the partition portion 160 for facilitating a partitioning (cutting) of the electronic arrangement 100 at the partition portion 160. It should be noted that the electronic arrangement 100 may alternatively comprise only one indentation at the partition portion 160, i.e. the indentation 310 of the insulating layer 150 or the indentation 320 of the first metal layer 130. It should be noted that features of the indentations 310, 320 such as the shape, the arrangement, etc., of the indentations may differ from that disclosed which are schematically indicated.

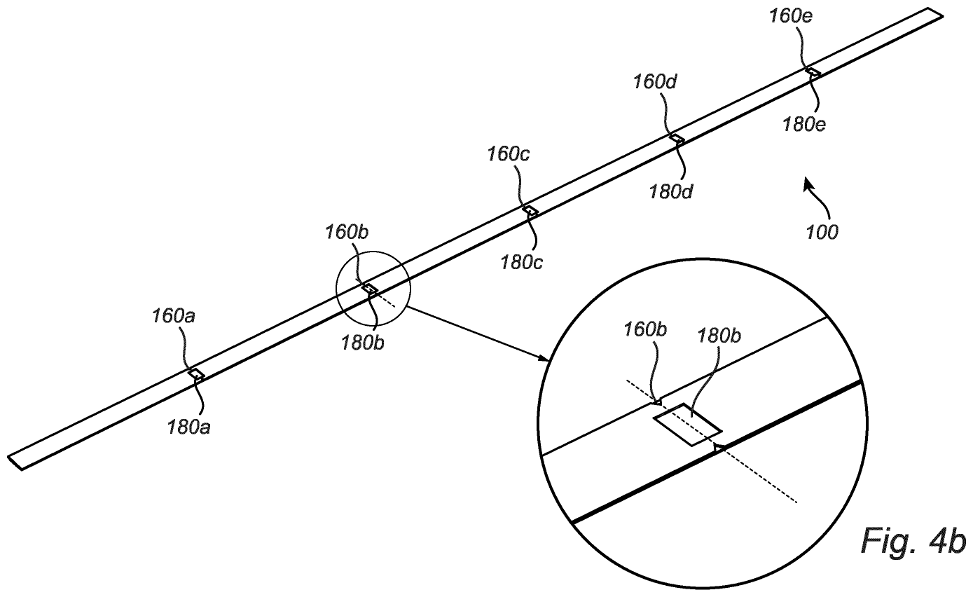

FIG. 4a is a schematic top view of an electronic arrangement 100 according to an exemplifying embodiment of the present invention. In this embodiment, the electronic arrangement 100 consists of six sub-sections 100a-f arranged in series along the axis A, wherein each of the six sub-sections 100a-f comprises six electronic components 110a-f. It will be appreciated that the number of sub-sections and the number of electronic components of the electronic arrangement 100 are arbitrary, and that the electronic arrangement 100 as depicted is merely shown as an example. The electronic arrangement 100 may be partitioned (cut) at one or more of the partition portions 160a-e which are arranged between two adjacently arranged electronic components of two adjacently arranged sub-sections of the electronic arrangement 100. The partitioning or cutting at the partition portions 160a-e along the axis B is schematically indicated by the pair of scissors 20a-e. It will be appreciated that the configuration of the electronic arrangement 100 at the partition portions 160a-e are the same or similar to that described in FIGS. 2a-b, and it is hereby referred to those figures for an increased understanding. Hence, the electronic arrangement 100 may be partitioned or cut at one or more of the partition portions 160a-e such that the second metal layer is undercut with respect to the first metal layer, resulting in a sufficiently large creepage distance between the first and second metal layers as described previously.

It should be noted that the electronic arrangement 100 in FIG. 4a may comprise connectors (not shown) at the partition portions 160a-e. In this way, the electronic arrangement 100 may be partitioned or cut such that one or more of the resulting sub-sections 100a-f may constitute an electronic arrangement. For example, an electronic arrangement 100 of a first length (e.g. about 0.61 m, which substantially corresponds to 2 foot) may be partitioned into two (sub) electronic arrangements of half the first length (i.e. about 0.30 m, which substantially corresponds to 1 foot).

FIG. 4b is a schematic bottom view of an electronic arrangement 100 according to the exemplifying embodiment of the present invention shown in FIG. 4a. Here, the electronic arrangement 100 shows the respective void 180a-e at the respective partition portion 160a-e, at which the electronic arrangement 100 may be partitioned or cut.

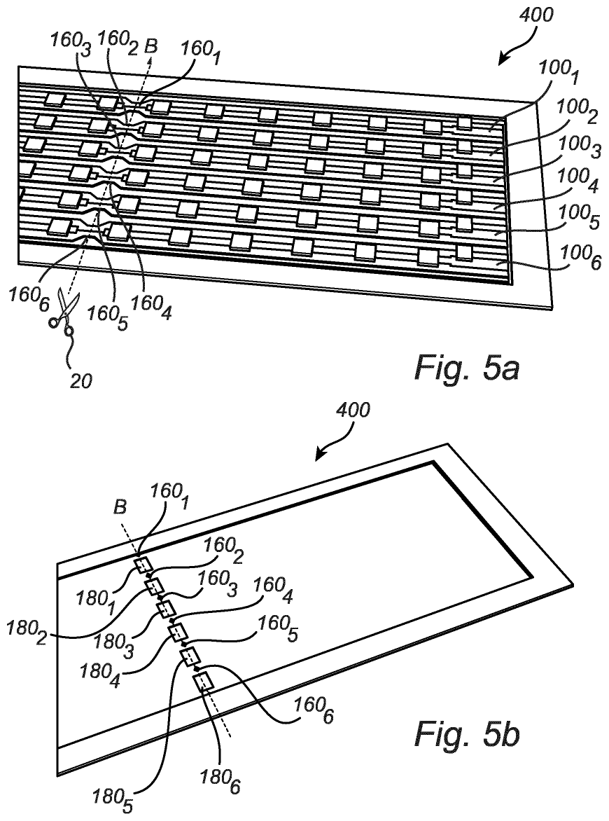

FIG. 5a is a schematic top view of an electronic board 400 according to an exemplifying embodiment of the present invention. The electronic board 400 comprises a plurality of electronic arrangements 100₁₋₆ according to any one of the preceding embodiments. The electronic arrangements 100₁₋₆ are arranged adjacently side-by-side in a first plane such that partition portions 160₁₋₆ of adjacently arranged electronic arrangements are arranged along second axis B in the first plane for partitioning the electronic board 400 along the second axis B. Hence, the electronic board 400 extends in two dimensions in a first plane and may be partitioned (cut) into smaller portions or segments along the second axis B. The partitioning or cutting at the partition portions 160₁₋₆ along the axis B is schematically indicated by the pair of scissors 20.

FIG. 5b is a schematic bottom view of an electronic board 400 according to the exemplifying embodiment of the electronic board 400 of FIG. 5a. Here, the electronic board 400 shows the respective void 180₁₋₆ of the respective partition portion 160₁₋₆ at which the electronic board 400 may be partitioned or cut along axis B.

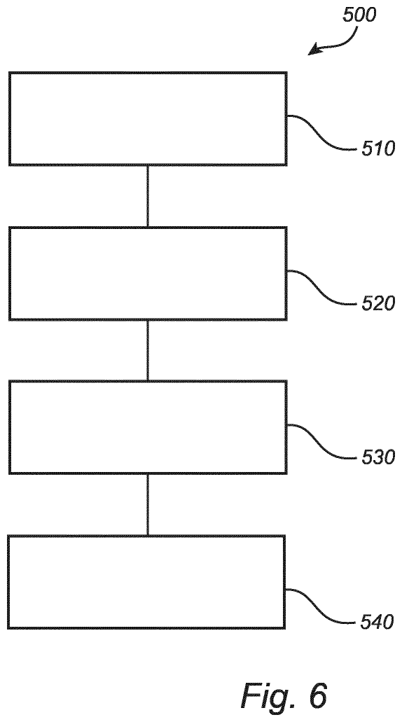

FIG. 6 is a schematic illustration of a method 500 of manufacturing an electronic arrangement according to an exemplifying embodiment of the present invention. The method 500 comprises the step of arranging 510 a first metal layer on an at least partially insulating layer, wherein the first metal layer and the at least partially insulating layer extend along a first axis. The step of arranging 510 the first metal layer may, as an example, comprise a lamination of a (dielectric) foil and a Cu foil. The method further comprises the step of providing 520 a second metal layer extending along the first axis and forming at least one void in the second metal layer having a width which extends parallel to the first axis. The step of providing 520 the second metal layer may, as an example, comprise a stamping of an Al substrate. As a further example, the method may comprise laminating the (dielectric) foil and the Cu foil onto the Al substrate, patterning the Cu-layer, adding a solder mask and pattering the solder mask. The method further comprises the step of arranging 530 a plurality of electronic components in an array on the carrier along the first axis. The step of arranging 530 the plurality of electronic components may, as an example, comprise applying a solder paste and arrange the electronic components on the carrier by a pick-and-place method. The method further comprises the step of forming 540 at least one partition portion between two adjacently arranged electronic components for partitioning the electronic arrangement along a second axis, B, of the at least one partition portion perpendicular to the first axis by arranging the second metal layer under the at least partially insulating layer such that the at least one void is intersected by the second axis and such that, at the second axis, the second metal layer is undercut with respect to the first metal layer, in a direction parallel to the first axis. It should be noted that the steps of the above-mentioned method 500 may be performed in the order as described, or alternatively, be performed in a different order.

The person skilled in the art realizes that the present invention by no means is limited to the preferred embodiments described above. On the contrary, many modifications and variations are possible within the scope of the appended claims. For example, the first metal layer, the second metal layer, the at least partially insulating layer, the partition portion(s), the void(s), etc., may have different dimensions and/or sizes than those depicted and/or described. For example, one or more of the layers may be thicker or thinner than exemplified in the figures.

1. An electronic arrangement, comprising
an array of electronic components arranged on a layer of a layer stack and along a first axis, A, and
the layer stack being formed as a carrier arranged to support the array of electronic components, wherein the carrier comprises, in a direction perpendicular to the first axis and perpendicular to the layer stack, a first metal layer and a second metal layer, wherein an at least partially insulating layer is arranged between the first and second metal layers, and
at least one partition portion arranged between two adjacently arranged electronic components for partitioning the electronic arrangement along a second axis, B, of the at least one partition portion, wherein the second axis extends perpendicular to the first axis,
wherein the second metal layer, at the at least one partition portion, comprises at least one void intersected by the second axis, wherein the at least one void has a width which extends parallel to the first axis, such that, at the second axis, the second metal layer is undercut with respect to the first metal layer, in a direction parallel to the first axis.

2. The electronic arrangement of claim 1, wherein the width of the at least one void is in the range of 0.7-1.1 times the distance (L) between adjacently arranged electronic components.

3. The electronic arrangement of claim 1, wherein the width of the at least one void is negatively correlated to the thickness of the at least partially insulating layer.

4. The electronic arrangement of claim 1, wherein the sum of the thickness of the at least partially insulating layer and half the width of the at least one void is 0.1-3 mm, preferably 0.5-1.2 mm, and most preferred 0.5-0.7 mm.

5. The electronic arrangement of claim 1, wherein the at least one void has a rectangular shape.

6. The electronic arrangement of claim 1, wherein the second metal layer comprises aluminum, Al.

7. The electronic arrangement of claim 1, wherein the thickness of the second metal layer is 0.1-1.6 mm, preferably 0.2-0.5 mm, and most preferred 0.24-0.36 mm.

8. The electronic arrangement of claim 1, wherein at least one of the at least partially insulating layer and the first metal layer comprises an indentation at the at least one partition portion.

9. The electronic arrangement of claim 1, wherein at least one of the electronic components comprises at least one light-emitting diode, LED.

10. An electronic board, comprising
a plurality of electronic arrangements according to claim 1, wherein the electronic arrangements are arranged side-by-side in a first plane such that partition portions of adjacently arranged electronic arrangements are arranged along the second axis in the first plane for partitioning the electronic board along the second axis.

11. A method of manufacturing an electronic arrangement, comprising the steps of:
forming a layer stack by
arranging a first metal layer on an at least partially insulating layer, wherein the first metal layer and the at least partially insulating layer extend along a first axis,
providing a second metal layer extending along the first axis and forming at least one void in the second metal layer having a width which extends parallel to the first axis,
arranging a plurality of electronic components in an array on the first metal layer along the first axis, and
forming at least one partition portion between two adjacently arranged electronic components for partitioning the electronic arrangement along a second axis, B, of the at least one partition portion perpendicular to the first axis by arranging the second metal layer under the at least partially insulating layer such that the at least one void is intersected by the second axis and such that, at the second axis, the second metal layer is undercut with respect to the first metal layer, in a direction parallel to the first axis.

12. The method of claim 11, wherein the at least one void has a rectangular shape.

13. The method of claim 11, wherein the second metal layer comprises aluminum, Al.

14. The method of claim 11, wherein the thickness of the second metal layer is 0.1-1.6 mm, preferably 0.2-0.5 mm, and most preferred 0.24-0.36 mm.

15. The method of claim 11, further comprising forming at least one indentation at the second axis in at least one of the at least partially insulating layer and the first metal layer at the at least one partition portion.
